(19) United States
(12) Patent Application Publication
(10) Pub. No.: US 2023/0275148 A1
(43) Pub. Date: Aug. 31, 2023

(54) SEMICONDUCTOR DEVICE

(71) Applicant: SUZHOU ORIENTAL SEMICONDUCTOR CO., LTD., Jiangsu (CN)

(72) Inventors: Yi GONG, Jiangsu (CN); Lei LIU, Jiangsu (CN); Wei LIU, Jiangsu (CN); Yuanlin YUAN, Jiangsu (CN)

(21) Appl. No.: 18/016,813

(22) PCT Filed: Nov. 19, 2021
(86) PCT No.: PCT/CN2021/131692

§ 371 Date: Jan. 18, 2023

(30) Foreign Application Priority Data
Feb. 19, 2021 (CN) 202110191691.8

(51) Int. Cl. H01L 29/78; H01L 29/10; H01L 29/06; H01L 29/36

(52) U.S. Cl. CPC H01L 29/7813; H01L 29/1095; H01L 29/0615; H01L 29/0684; H01L 29/36

(57) ABSTRACT

Provided is a semiconductor device. The semiconductor device includes a semiconductor substrate, p-type body regions disposed in the semiconductor substrate, and p-type columns. The p-type body regions are in contact with a source metal layer. The p-type columns are disposed in the semiconductor substrate, each of the p-type columns is below a respective one of the p-type body regions. The semiconductor substrate includes at least one first region, and a region of the semiconductor substrate outside the at least one first region is a second region. A p-type body region of p-type body regions in the first region is provided with a first p-type body region contact region, and the source metal layer is in contact with the first p-type body region contact region to form an ohmic contact. Each of p-type body regions in the second region forms no ohmic contact with the source metal layer.

### CROSS-REFERENCE TO RELATED APPLICATION(S)

This is a national stage application filed under 37 U.S.C. 371 based on International Patent Application No. PCT/CN2021/131692, filed Nov. 19, 2021, which claims priority to Chinese Patent Application No. 202110191691.8 filed with the China National Intellectual Property Administration (CNIPA) on Feb. 19, 2021, the disclosures of which are incorporated herein by reference in their entireties.

### TECHNICAL FIELD

The present disclosure belongs to the technical field of semiconductor devices, and for example, relates to a power semiconductor device.

### BACKGROUND

For a power semiconductor device in the related art, a Miller capacitance of the device is typically reduced so that a switching speed is improved so as to reduce a switching loss. However, too fast a switching speed results in large voltage and current oscillations, which leads to a serious electromagnetic interference (EMI) when the power semiconductor device is applied.

### SUMMARY

The present application provides a semiconductor device, so as to reduce an EMI caused when the semiconductor device is applied.

The present application provides a semiconductor device.

The semiconductor device includes a semiconductor substrate, p-type body regions disposed in the semiconductor substrate, and p-type columns.

The p-type body regions are in contact with a source metal layer.

The p-type columns are disposed in the semiconductor substrate, where each of the p-type columns is below a respective one of the p-type body regions.

The semiconductor substrate includes at least one first region, and a region of the semiconductor substrate outside the at least one first region is a second region.
a p-type body region of p-type body regions in the at least one first region is provided with a first p-type body region contact region, and the source metal layer is in contact with the first p-type body region contact region to form an ohmic contact.

Each of p-type body regions in the second region forms no ohmic contact with the source metal layer.

### BRIEF DESCRIPTION OF DRAWINGS

FIG. 1 is a top view of a first embodiment of a semiconductor device according to the present application;

FIG. 2 is a sectional view of a structure shown in FIG. 1 along an AA direction; and

FIG. 3 is a top view of a second embodiment of a semiconductor device according to the present application.

### DETAILED DESCRIPTION

The technical solution of the present application is completely described hereinafter in conjunction with drawings in embodiments of the present application. It is to be understood that the terms used in the present application such as “have”, “comprise”, and “include” do not exclude the presence of at least one other element or a combination thereof.

It is to be understood by those skilled in the art that a power semiconductor device chip includes a cell region and a terminal region. The cell region is a current working region, and the terminal region is configured to increase withstand voltages of cells on the edge of the cell region. The semiconductor device described in the embodiments of the present application refers to the cell region in the power semiconductor device chip.

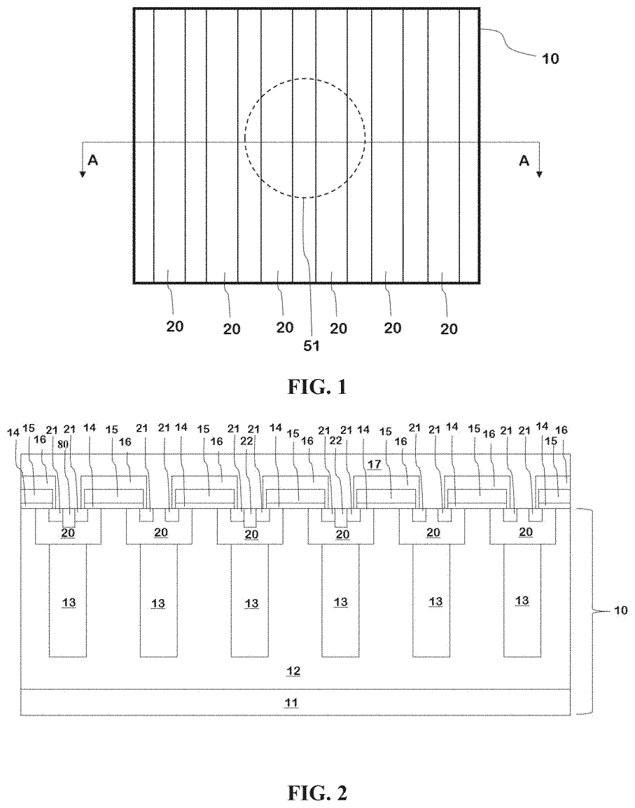

FIG. 1 is a top view of a first embodiment of a semiconductor device according to the present application, and FIG. 2 is a sectional view of a structure shown in FIG. 1 along an AA direction. As shown in FIGS. 1 and 2, the semiconductor device of the present application includes a semiconductor substrate 10 which is typically a silicon substrate. The semiconductor substrate 10 includes an n-type drain region 11 and an n-type drift region 12 disposed above the n-type drain region 11. The semiconductor device of the present application includes p-type body regions 20 disposed in the semiconductor substrate 10, where each of the p-type body regions 20 forms a PN junction structure with the n-type drift region 12. The cell region of the semiconductor device chip includes several p-type body regions. Only six p-type body regions 20 are exemplarily shown in FIGS. 1 and 2. The semiconductor device of the present application further includes n-type source regions 21 disposed in the p-type body regions 20, where the p-type body regions 20 and the n-type source regions 21 are each in contact with the source metal layer 17.

The semiconductor device of the present application includes p-type columns 13 disposed in the semiconductor substrate 10, where each of the p-type columns is below a respective one of p-type body regions 20. Each of the p-type columns 13 forms a PN junction structure with the n-type drift region 12, and a charge balance between a p-type column 13 and the adjacent n-type drift region 12 is formed. As shown in FIG. 2, each of the p-type columns 13 may be in contact with the respective one of the p-type body regions 20. Thus, the p-type columns 13 are connected to source voltages. Optionally, the p-type columns 13 may be not in contact with the p-type body regions 20, that is, the p-type columns 13 are configured to float. It is to be noted that the p-type columns 13 may be manufactured by multiple different processes, and the p-type columns obtained in this manner have different shapes.

As shown in FIG. 1, the semiconductor substrate 10 includes at least one first region 51 in a top view of an upper surface of the semiconductor substrate 10. The number and shape of the at least one first region 51 are not specifically limited in the present application. Only one first region 51 is exemplarily shown in FIG. 1 and the first region 51 has a circular structure. A region of the semiconductor substrate 10 outside the at least one first region 51 is defined as a second region.

A p-type body region 20 of p-type body regions 20 in the at least one first region 51 is provided with a first p-type body region contact region 22. The source metal layer 17 is in contact with the first p-type body region contact region 22 to form an ohmic contact. The doping concentration of the first p-type body region contact region 22 is higher than the doping concentration of a p-type body region 20. Therefore, the first p-type body region contact region 22 increases the doping concentration of the position where the p-type region 20 is in contact with the source metal layer 17 so that each of the p-type body regions 20 in the at least one first region 51 forms the ohmic contact with the source metal layer 17.

Each of p-type body regions 20 in the second region has a relatively low doping concentration. Therefore, each of the p-type body regions 20 in the second region forms no ohmic contact with the source metal layer 17 after being in contact with the source metal layer 17. Optionally, a second p-type body region contact region 80 may be formed in a p-type body region 20 of the p-type body regions 20 in the second region. However, the doping concentration of the second p-type body region contact region 80 is lower than the doping concentration of the first p-type body region contact region 22 so that the second p-type body region contact region 80 forms no ohmic contact with the source metal layer 17 after being in contact with the source metal layer 17, or the second p-type body region contact region 80 forms, after being in contact with the source metal layer 17, the ohmic contact having a relatively high resistance with the source metal layer 17.

As shown in FIG. 2, the semiconductor device of the present application further includes gate structures, each of the gate structures includes a gate dielectric layer 14 and a gate 15. Each of the gate structures is isolated from the source metal layer 17 via an interlayer insulating layer 16. In FIG. 2, the gate structures of the semiconductor device of the present application are planar gate structures. Optionally, the gate structures of the semiconductor device of the present disclosure may be trench gate structures.

In the semiconductor device of the present application, each of the p-type body regions 20 in the at least one first region 51 forms the ohmic contact with the source metal layer 17 via the first p-type body region contact region 22, and each of the p-type body regions 20 in the second region forms no ohmic contact with the source metal layer 17. The p-type body regions 20 forming no ohmic contact have unfixed electric potentials, which results in changes in a threshold voltage Vth. In addition, if a p-type body region 20 forming no ohmic contact is farther away from a p-type body region 20 forming the ohmic contact, a greater difference exists between a threshold voltage Vth of the p-type body region forming no ohmic contact and a threshold voltage Vth of the p-type body region forming the ohmic contact. That is, a difference between a threshold voltage of a p-type body region in the second region close to the first region and a threshold voltage of a p-type body region in the first region is less than a difference between a threshold voltage of a p-type body region in the second region far away from the first region and the threshold voltage of the p-type body region in the first region. Thus, the semiconductor device of the present application has a gradually changing threshold voltage Vth. A current and a voltage are not easily changed abruptly when the semiconductor device is turned on and off, which may reduce a voltage oscillation, a current oscillation, and an EMI caused when the semiconductor device is applied and may improve the reverse recovery characteristic of the device.

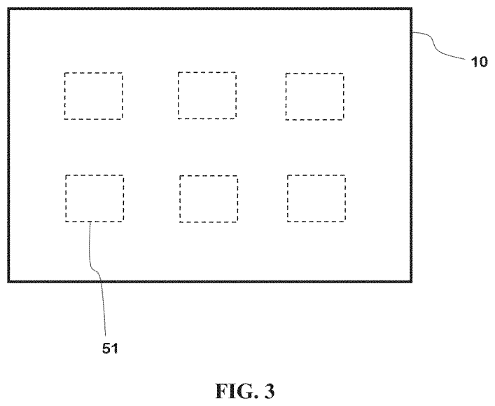

FIG. 3 is a top view of a second embodiment of the semiconductor device according to the present application. In FIG. 3, a semiconductor substrate 10 includes six first regions 51. The first regions 51 are rectangular. Optionally, each of the first regions 51 may be a regular pattern such as a polygon (for example, a triangle, a square, a regular polygon, a rectangle, a parallelogram, and a trapezoid), a circle, or an ellipse. Alternatively, each of the first regions 51 may be an irregular pattern. The shape of the first regions 51 is not limited in the embodiments of the present application. A top-view shape of each of the first regions 51 only needs to be a closed pattern, for example, a closed pattern which straight lines and/or curves are successively connected end to end to form.

In the top views shown in FIGS. 1 and 3, that the first region is surrounded by the second region is used as an example for the description. It is to be noted that a relative positional relationship between the first region and the second region is not limited in the embodiments of the present application. The relative positional relationship may be as shown in FIGS. 1 and 3, that the second region is surrounded by the first region, or that the first region and the second region are successively disposed along a direction parallel to the plane where the semiconductor substrate is located.

What is claimed is:

1. A semiconductor device, comprising:
a semiconductor substrate;
p-type body regions disposed in the semiconductor substrate, wherein the p-type body regions are in contact with a source metal layer; and
p-type columns disposed in the semiconductor substrate, wherein each of the p-type columns is below a respective one of the p-type body regions;
wherein the semiconductor substrate comprises at least one first region, and a region of the semiconductor substrate outside the at least one first region is a second region;
a p-type body region of p-type body regions in the at least one first region is provided with a first p-type body region contact region, and the source metal layer is in contact with the first p-type body region contact region to form an ohmic contact; and
each of p-type body regions in the second region forms no ohmic contact with the source metal layer.

2. The semiconductor device according to claim 1, wherein a shape of the at least one first region comprises at least one of a polygon, a circle, or an ellipse.

3. The semiconductor device according to claim 1, wherein a p-type body region of the p-type body regions in the second region is provided with a second p-type body region contact region, and a doping concentration of the second p-type body region contact region is lower than a doping concentration of the first p-type body region contact region.

4. The semiconductor device according to claim 3, wherein the source metal layer is in contact with the second p-type body region contact region but no ohmic contact is formed between the source metal layer and the second p-type body region contact region.

5. The semiconductor device according to claim 1, further comprising n-type source regions disposed in the p-type body regions, wherein the n-type source regions are in contact with the source metal layer.

6. The semiconductor device according to claim 1, wherein each of the p-type columns is in contact with the respective one of the p-type body regions.

7. The semiconductor device according to claim 1, wherein the semiconductor substrate comprises an n-type drain region and an n-type drift region disposed above the n-type drain region, and each of the p-type body regions forms a PN junction structure with the n-type drift region.

8. The semiconductor device according to claim 1, further comprising gate structures, each of the gate structures comprises a gate dielectric layer and a gate.

9. The semiconductor device according to claim 8, wherein the gate structures are planar gate structures or trench gate structures.

10. The semiconductor device according to claim 8, wherein each of the gate structures is isolated from the source metal layer via an interlayer insulating layer.

11. The semiconductor device according to claim 1, wherein the semiconductor substrate comprises an n-type drain region and an n-type drift region disposed above the n-type drain region, each of the p-type columns forms a PN junction structure with the n-type drift region, and a charge balance between a p-type column of the p-type columns and a adjacent n-type drift region is formed.

12. The semiconductor device according to claim 1, wherein the p-type columns are configured to float.
